(19) United States
(12) Patent Application Publication
(10) Pub. No.: US 2005/0189013 A1
(43) Pub. Date: Sep. 1, 2005

(54) Process for manufacturing photovoltaic cells

(76) Inventor: Oliver Hartley, Kingston (GB)

Correspondence Address: CAROL WILSON;BP AMERICA INC., MAIL CODE 5 EAST, 4101 WINFIELD ROAD, WARRENVILLE, IL, 60555, US

(21) Appl. No.: 11/015,466

(22) Filed: Dec. 17, 2004

Related U.S. Application Data
(60) Provisional application No. 60/532,268, filed on Dec. 23, 2003.

(51) Int. Cl. H01L 31/00

(52) U.S. Cl. 136/256; 438/98

(57) ABSTRACT

A process for making a photovoltaic cell using a semiconductor wafer doped with a first dopant and having a front surface and a back surface, the process comprising the steps of forming a first layer on the front surface of the wafer, the first layer comprising a second dopant of a conductivity type opposite the first dopant; depositing a surface coating on the back surface; forming grooves in the front surface; adding dopant to the groove of a conductivity type opposite the first dopant subsequent to depositing the surface coating on the back surface; removing the surface coating from the back surface after adding dopant to the grooves; forming a back contact over the back surface after removal of the surface coating; and adding conductive material to the grooves.

This application claims the benefit of U.S. Provisional Patent Application No. 60/532,268, filed on Dec. 23, 2003.

### BACKGROUND OF THE INVENTION

This invention relates to a process for manufacturing photovoltaic cells. More particularly, this invention relates to a process useful for manufacturing photovoltaic cells that are highly efficient in converting light energy, and particularly solar energy, to electrical energy. One of the most important features of a photovoltaic cell is its efficiency in converting light energy from the sun into electrical energy. Thus, the art is continuously striving to not only reduce the cost of manufacturing photovoltaic cells, but also to improve their efficiency in converting light energy into electrical energy. This invention also relates to highly efficient solar cells and semiconductor wafers that can be used to manufacture highly efficient solar cells.

Typically, a plurality of photovoltaic cells are arranged in one or more panels or modules in order to generate an amount of power required for a desired commercial or consumer application.

Photovoltaic cells can be fabricated from a variety of semiconductor materials. Silicon, however, is generally used because it is readily available at reasonable cost and because it has the proper balance of electric, physical and chemical properties for use to fabricate photovoltaic cells.

In a typical procedure for the manufacture of photovoltaic cells, using silicon as the selected semiconductor material, the silicon is doped with a dopant of either positive or negative conductivity type, formed into either single crystal ingots of silicon or blocks of what the art refers to a multi-crystalline silicon, and these ingots or blocks are cut into thin substrates, also referred to as wafers, by various slicing or sawing methods known in the art. However, these are not the only methods use to obtain suitable semiconductor wafers for the manufacture of photovoltaic devices and particularly photovoltaic cells. The surface of the wafer intended to face incident light when the wafer is formed into a photovoltaic cell is referred to herein as the front face or front surface, and the surface of the wafer opposite the front face is referred to herein as the back face or back surface. By convention, positive conductivity type is commonly designated as “p” or “p-type” and negative conductivity type is designated as “n” or “n-type”. However, “p” and “n” are used herein only to indicate opposing conductivity types.

A p-doped wafer is exposed to a suitable n-dopant to form an emitter layer and p-n junction. Typically, the n-doped layer or emitter layer is formed by first depositing the n-dopant onto the surface of the p-doped wafer using techniques commonly employed in the art such as chemical vapor deposition or other deposition methods and, after such deposition the n-dopant is driven into the surface of the silicon substrate to further diffuse the n-dopant into the wafer surface. This “drive-in” step is commonly accomplished by exposing the wafer to heat, often in combination with a gas stream comprising POCl₃ and oxygen. A p-n junction is thereby formed at the boundary region between the n-doped layer and the p-doped silicon substrate. The wafer surface can be textured prior to the n-doping to form the emitter layer.

In order to utilize the electrical potential generated by exposing the p-n junction to light energy, the photovoltaic cell is typically provided with a conductive front electrical contact and a conductive back or rear electrical contact. Such contacts are typically made of one or more highly conducting metals and are, therefore, typically opaque. Since the front contact is on the side of the photovoltaic cell facing the sun or other source of light energy, it is generally desirable for the front contact to take up the least amount of area of the front surface of the cell as possible yet still capture the electron charges generated by the incident light interacting with the cell. If the front contact is too large in area, the amount of shading caused by the opaque contact itself will reduce the amount of light impinging on the cell and result in the undesirable reduction of cell efficiency. However, it is still necessary for the front contact to be of sufficient area and to be properly positioned on the front surface of the cell so that it is able to efficiently capture the electron charges generated by the light radiation interacting with the doped silicon layers.

A number of methods have been developed in the art for applying front contacts to a crystalline, multicrystalline silicon, or other semiconductor wafer. One known method is to form a buried contact. In the buried-type of front contact, the front contact is made by scribing or cutting a pattern of scribes or grooves into the surface of the wafer in an open grid pattern and thereafter filling the grooves with a conducting material such as a highly conducting metal. One suitable method for forming the grooves for the buried grid contact is to use a laser. Methods for forming buried-type contacts are described in, for example, U.S. Pat. No. 4,726,850, to Wenham et al., which is incorporated herein by reference in its entirety.

One method for making photovoltaic cells having buried-type front contacts follows a processing sequence as follows. The n-layer is created in a p-type crystalline or multicrystalline silicon wafer by diffusing phosphorus into the p-type wafer thereby forming a p-n junction. A layer of a dielectric material is applied to the surface of the wafer having the p-n junction as an anti-reflective coating, for example, a layer of silicon nitride. This will, ultimately, be the light receiving side of the cell. Using a laser, narrow and deep grooves are cut through the dielectric layer and into the silicon substrate in a pattern that will form the front buried contact. The grooves are etched with a chemical solution, such as sodium hydroxide, to further form the grooves. Additional phosphorous is diffused into the walls of the grooves. Such doping of the surfaces within the grooves improves the efficiency of the cell. The back contact is added to the cell, typically by one or more sputtering or metal evaporation techniques known to those of skill in the art. Prior to adding the back contact, a back surface field can be added to the wafer by heavily p-doping the back surface of the wafer. Such p-doping can be achieved by applying aluminum or boron to the back surface of the wafer followed by a high temperature sintering step. The grooves in the front of the cell are filled with a conductor, for example, one or more of silver, nickel, or copper, by one or more methods such as electrolytic or electroless plating, or using a paste followed by firing the paste to form the metal contact. An edge isolation step separates any electrical connections between the front and back of the cell. A process for producing a photovoltaic cell having a buried front contact using, inter alia, processing steps in the sequence of silicon nitride coating of the front surface, laser grooving, sodium hydroxide etch, diffusion of grooves, applying back contact and firing, applying front contact and firing, and edge isolation, is disclosed in U.S. Pat. No. 4,726,850 (disclosed as “Sequence B” therein), as being one which may yield a higher efficiency photovoltaic cell.

While such a processing sequence results in an efficient, buried contact-type of photovoltaic cell, the art, as mentioned above, is continually striving to prepare photovoltaic cells, particularly cells that can be manufactured on a commercial production scale, that are higher in efficiency. For example, in the process described above it is believed that the n-type dopant, such as phosphorus, applied to and diffused into the grooves cut into the wafer, also diffuses into the rear surface of the wafer thereby adversely affecting the formation of the back surface field and resulting in a reduction of the efficiency of the cell.

The art therefore needs a process to manufacture photovoltaic cells having improved efficiency where such process is applicable to commercial scale production. The present invention provides such process.

### SUMMARY OF THE INVENTION

This invention is a process for making a photovoltaic cell using a semiconductor wafer doped with a first dopant, the wafer having a front surface and a back surface, the process comprising the steps of (a) forming a first layer on the front surface of the wafer, the first layer comprising a second dopant of a conductivity type opposite the first dopant; (b) depositing a surface coating on the front surface over the first layer; (c) depositing a surface coating on the back surface; (d) forming grooves in the front surface after depositing the surface coating thereon; (e) adding a second dopant to the grooves subsequent to depositing the surface coating on the back surface; (f) removing the surface coating from the back surface after doping the grooves; (g) forming a back contact over the back surface after removal of the surface coating; and (h) adding a conductive material to the grooves to form a front contact.

### BRIEF DESCRIPTION OF THE DRAWING

FIG. 1 shows a cross-section of a part of a photovoltaic cell made in accordance with an embodiment of this invention.

FIG. 2 shows a schematic, cross-section view of a coated semiconductor substrate made in accordance with an embodiment of this invention. Such coated substrates are useful in the process of making photovoltaic cells.

### DETAILED DESCRIPTION OF THE INVENTION

The invention will now be described using as an example an embodiment of the invention whereby a photovoltaic cell is made using a p-doped silicon wafer. However, it is to be understood that the invention is not limited thereby and is, for example, applicable to other semiconductor materials.

A silicon wafer useful in the process of this invention for preparing photovoltaic cells is typically in the form of thin, flat shape. The silicon may comprise one or more additional materials, such as one or more semiconductor materials, for example germanium, if desired. Although boron is widely used as the p-type dopant, other p-type dopants, for example gallium or indium, will also suffice. Boron is the preferred p-type dopant. Combinations of such dopants are also suitable. Suitable wafers are typically obtained by slicing or sawing p-doped silicon ingots, such as single crystal ingots of mono-crystalline wafers, to form mono-crystalline wafers, such as the so-called Czochralski (Cz) silicon wafers. Suitable wafers can also be made by slicing or sawing blocks of cast, p-doped multi-crystalline silicon. Silicon wafers can also be pulled straight from molten silicon using processes such as Edge-defined Film-fed growth technology (EFG) or similar techniques. Although the wafers can be any shape, wafers are typically circular, square or pseudo-square in shape. By “pseudo-square” is meant a predominantly square shape usually with rounded corners. Thus, in general, the wafers useful in this invention are flat, typically round, square or pseudo-square in shape and are thin. For example, a wafer useful in this invention can be about 50 microns thick to about 400 microns thick. Usually, however, the wafers can be about 200 to about 300 microns thick. If circular they can have a diameter of about 102 to about 178 millimeters. If square or pseudo square, they can have a width of about 100 millimeters to about 150 millimeters with rounded corners having a diameter of about 127 to about 178 millimeters. The wafers useful in the process of this invention, and consequently the photovoltaic cells made by the process of this invention, can have a surface area of about 140 to about 160 square centimeters. The doped wafers useful in the process of this invention can have a resistivity of about 0.1 to about 10 ohm.cm, typically of about 0.5 to about 2.0 ohm.cm. The wafers used to manufacture the photovoltaic cells of this invention are preferably made of p-doped, mono-crystalline silicon. Suitable wafers used in the process of this invention are commercially available from, for example, Bayer Solar GmbH, PV Silicon GmbH, Pillar and other sources. Although the term wafer as used herein preferably means the wafers obtained by the methods described, particularly by the sawing or cutting of ingots or blocks of silicon, it is to be understood that the term wafer can also include any other suitable semiconductor substrate useful for preparing photovoltaic cells by the process of this invention.

The wafer is preferably textured, preferably by one or more texturing techniques that result in an anisotropically textured surface. For example the wafer can be suitably textured using chemical etching, plasma etching and mechanical scribing. The wafer can be etched to form an anisotropically textured surface by treating the wafer in an aqueous solution of a base, such as sodium hydroxide, at an elevated temperature, for example about 70° C. to about 90° C. for about 10 to about 120 minutes. The aqueous solution may contain an alcohol, such as isopropanol. The textured wafer is typically subsequently cleaned by immersion in hydrofluoric and then hydrochloric acid with intermediate and final rinsing in de-ionized water, followed by drying. The optional texturing step is preferably done prior to the formation of the emitter layer.

An n-type dopant is applied to the wafer to produce an emitter layer and a p-n junction. Such n-doping can be accomplished by depositing the n-dopant onto the wafer and then heating the wafer to “drive” the n-dopant into the surface of the wafer. Gaseous diffusion can be used to deposit the n-dopant onto the wafer surface; however, other methods can also be used, such as ion implantation, solid source diffusion, or still other methods used in the art to create an n-doped layer and a p-n junction, preferably proximal to the wafer surface. Phosphorus is a preferred n-dopant, but one or more other suitable n-dopants can be used. For example, one or more of phosphorus, arsenic, antimony or lithium can be used. If, for example, phosphorus is used as the dopant, it can be applied to the wafer using phosphorus oxychloride (POCl₃), or phosphorus containing pastes. In the process of this invention, the preferred procedure is to add the n-dopant as phosphorus by subjecting the wafers to an atmosphere of phosphorus oxychloride and molecular oxygen at an elevated temperature of about 700° C. to about 850° C. to deposit a layer of a phosphorus glass on the wafer. Such glass layer can be about 5 to about 20 nanometers thick, more typically from about 10 to about 15 nanometers. The n-dopant is preferably applied to—and thus the emitter layer is preferably formed on—only one surface, the front surface, of the wafer. This can conveniently be accomplished by placing two wafers back-to-back when they are exposed to the material for adding the n-dopant. Other methods for adding the n-dopant to only the front surface of the wafer can, however, be used, such as placing the wafers on a flat surface to shield the back surface of the wafer from being exposed to the dopant material.

In the process of this invention the back surface of the wafer, preferably after forming the emitter layer as described above, is coated with a surface coating. As will be described in more detail below, the surface coating is added to the back surface of the wafer which is believed to reduce, and preferably prevent, exposure of the back surface of the wafer to an n-type dopant during a step in the process wherein a dopant is added to grooves in the wafer used for forming the buried front contact. The surface coating can be any suitable coating that will reduce or, preferably, prevent exposure of the back surface of the wafer to the n-dopant when the n-dopant is applied to the grooves. The surface coating should, preferably, be easy to apply to the wafer and it should also be removable so it can be taken off prior to adding an electrical contact to the back surface of the water. The coating can be, for example, silicon nitride (SiN), silicon dioxide (SiO₂), or any other layer that preferably withstands temperatures up to about 1000° C. and preferably does not have any adverse effects on solar cell performance.

In the preferred embodiment of this invention, the surface coating applied to the back surface of the wafer is a dielectric layer of the same type of surface coating that is preferably added to the front surface of the wafer as an anti-reflective coating after formation of the emitter layer on the front surface. Such anti-reflective coating can be, for example, a layer of a dielectric such as tantalum oxide, silicon dioxide, titanium oxide, or silicon nitride, which can be added by methods known in the art, for example, plasma enhanced chemical vapor deposition (PECVD), low pressure chemical vapor deposition (LPCVD), thermal oxidation, screen printing of pastes, inks or sol gel, etc. Combinations of coatings can also be used. The preferred anti-reflective coating for the buried contact type of solar cell is silicon nitride. The silicon nitride can be added, for example, by PECVD. Preferably, in the process of this invention the silicon nitride layer is applied using low pressure chemical vapor deposition (LPCVD). A common method for applying the silicon nitride by LPCVD is to expose the wafer to an atmosphere of silicon compound, such as dichlorosilane, and ammonia at an elevated temperature of about 750° C. to about 850° C.

While the surface coating for the back surface, such as a dielectric layer, can be added in separately from adding a surface coating to the front surface, for example adding the surface coating to the front surface first, or the back surface first, the preferred process in accordance with this invention is to add an anti-reflective coating to the front and the back surfaces of the wafer at the same time or at least in the same process step apparatus used to apply the coating.

At the time of application, the surface coating added to the front and back surfaces of the wafer is preferably greater than about 100 nanometers, and preferably less than about 140 nanometers. The coating can be, for example, about 110 to about 130 nanometers thick. The coating on the front and back surface can be of the same or different thickness. Preferably they are about the same thickness when applied. During subsequent process steps, the layer applied to the front surface, such as the preferred silicon nitride, will typically diminish in thickness. The front anti-reflective coating on the finished solar cell should be, preferably, about 70 to about 100 nanometers thick.

Grooves are formed in the front surface of the substrate. These are the grooves that will become the front contacts after the grooves are metallized or otherwise filled with a conductor. The grooves are suitably cut or otherwise formed in the front surface of the wafer, all the way through an anti-reflective coating on the front surface. One or more mechanical methods, such as mechanical abrasion, or chemical methods, such as chemical etching, can be used to form the grooves. The grooves are, however, preferably formed by laser scribing. A suitable laser is a Nd:YAG laser or Nd:YVO₄ laser Q-switched at a frequency of about 10 to about 150 kHz. The laser can traverse the wafer surface at a velocity of about 100 to about 10,000 millimeters/second, for example at about 1000 millimeters/second. A first set of grooves are suitably added to the front surface of the wafer in a pattern of parallel lines distributed over the entire front surface of the wafer. The grooves can be about 0.3 to about 2 millimeters apart and can be, preferably, about 10 to about 40 micrometers in width, and about 10 to about 50 micrometers in depth. A second set of grooves is typically added perpendicular to and intersecting the first set of grooves. Such second set of grooves is preferably added as a “bundle” of grooves, or as two or more “bundles” of grooves. This second set of grooves is preferably arranged so that the grooves in each bundle are closely spaced, for example, about 10 to about 50 micrometers apart. There can be about 10 to about 20 grooves in each bundle. Thus the bundle is about 0.5 to about 1.5 millimeters wide. On a 125 millimeters pseudo-square wafer the bundles can be about 55 to about 65 millimeters apart from each other on the wafer. Such bundle or bundles of grooves can function as bus bars that electrically connect the first set of grooves and can also function as contact points for electrical leads that are attached to the cell. U.S. Pat. No. 4,726,850 to Wenham et al, as mentioned above, discloses methods for making grooves in silicon substrates for buried contacts.

The grooves are typically cleaned and typically etched by one or more chemical etching techniques. For example the cutting or scribing process generally results in the formation of undesirable silicon debris in and around the grooves. Consequently, it is desirable to remove such debris. It is also desirable to further etch the grooves. The grooves can be cleaned and etched by treating the wafer with an aqueous solution of base, such as sodium hydroxide, at a temperature of about 50° C. to about 70° C. for a time sufficient to eliminate or reduce the silicon debris and to etch the walls of the grooves by a few, for example about 1 to about 10 micrometers. After such cleaning and etching procedure, the wafers can be cleaned by immersing the wafers in hydrofluoric acid and hydrochloric acid, with intermediate and final rinsing in de-ionized water.

The grooves, typically after the preferred cleaning, etching and washing procedures, are preferably doped to add additional n-dopant to the grooves. As described above for the formation of the emitter layer and p-n junction, the same dopants and doping procedures can be used. However, in the preferred process of this invention the grooves are further doped using phosphorus oxychloride. For example, the wafers can be treated in an atmosphere of phosphorus oxychloride and molecular oxygen at a temperature of about 850° C. to about 1000° C. to dope the exposed silicon surfaces in the grooves on the front surface of the wafer. After such doping, the groove surfaces preferably have a sheet resistivity of about 5 to about 15 ohm/square. In the stage of the invented process where the grooves are doped, the wafer has a surface coating on the back surface of the wafer. In the preferred embodiment of the process of this invention, the coating is silicon nitride. Such coating, it is believed, eliminates, or at least greatly reduces the exposure of the back surface of the silicon wafer to the n-dopant used to dope the grooves. Thus, it is preferred that the surface coating on the back surface is of a material and of a thickness that prevents or at least greatly reduces the exposure of the back silicon surface to the material used to dope the grooves with an n-dopant during the groove doping procedure, but also made of a material and is of a thickness that can be removed prior to adding an electrical contact to the back surface of the silicon wafer.

As just described above, prior to adding a back electrical contact to the silicon wafer, the surface coating on the back contact is removed. Any suitable method can be used to remove the surface coating depending on, of course, what was used for the surface coating and how it was added. For example, it can be removed by mechanical abrasion or by a chemical etching procedure. In the preferred process of this invention, a layer of silicon nitride or other anti-reflective coating is used to coat the back surface and such dielectric coating is selectively removed from the back surface without attacking the front surface preferably by using plasma etching. In one suitable method for plasma etching the back surface of the silicon surface, the surface coating on the back surface of the wafer is exposed to a gas plasma formed with, for example, a Freon (for example, C₂F₆) and molecular oxygen. In order to remove only the coating on the back surface and not remove the coating on the front surface of the silicon wafer when using a process like plasma etching, some step has to be taken in order to preferentially remove only the coating on the back surface. This can be accomplished by, for example, placing two wafers with their front surfaces facing and pressed against each other. In that way, the front surface is protected from exposure to the plasma or other method used to remove the surface coating from the back surface of the wafer. Another method is to place the wafer with its front surface on a suitable tray or plate, such as a plate of glass or tray with a suitable recess, so that the front surface is protected during the step to remove the surface coating from the back surface of the wafer. If a means such as a mechanical abrasion is used to remove the coating, then such protection of the front surface may not be required.

Preferably, the process of this invention includes the formation of a back surface field to increase the efficiency of the photovoltaic cell. A back surface field (BSF) can be generated by forming a p++ layer in the back surface of the wafer. A p++ layer is a layer heavily doped with a p-type substance. Heavily doped means, preferably, that the concentration or level of dopant in the p++ layer or BSF is substantially greater doping than the concentration or level of p-dopant in the rest of the body of the wafer. For example, the concentration of dopant in a BSF layer in an embodiment of this invention can be about 10 to about 1000, or 10 to about 100 times the concentration of p-dopant present in the body of the silicon wafer. The BSF layer is advantageously formed by alloying a substance into the back surface of the silicon wafer. Aluminum is typically used but any substance can be used which is capable of alloying with the silicon and resulting in a p++ BSF layer. In one suitable procedure, aluminum, or other alloying substance such as, for example, boron, gallium or indium, or a combination of one or more thereof, is first deposited onto the back surface of the substrate. The aluminum or other alloying substance can be applied using a screen printing technique or it can be applied by some other method known the art such as one or more sputtering techniques. The wafer is thereafter fired at a temperature sufficient to alloy the aluminum or other substance, as mentioned above, to the silicon wafer substrate thereby creating a back surface field. Preferably such a temperature is about 900° C. to about 1000° C. The firing or sintering suitably takes place in an atmosphere comprising molecular oxygen, for example, and atmosphere comprising molecular oxygen and nitrogen.

In one embodiment of this invention to form a BSF, an aluminum layer is applied to the back surface by a magnetron sputtering technique. The aluminum layer is preferably applied to a thickness of about 0.2 to about 2.0 microns. Thereafter, the wafer is fired at an elevated temperature, for example, at a temperature of about 800° C. to about 1000° C. for about 10 to about 60 minutes, preferably in an atmosphere containing molecular oxygen, such as an atmosphere of molecular oxygen mixed with nitrogen gas.

In order to complete the formation of the front, buried contacts, they are filled with a conductive material. The conductive material is preferably one or more highly conductive metals such as silver, nickel, tin, copper, gold, platinum or other highly conductive metal. The grooves can be filled with such metal by one or more techniques known to those of skill in the art such as by filling grooves with a paste containing the metal by, for example, using a squeegee to press paste into the grooves, and thereafter heating the wafer to an elevated temperature and for a time to convert the paste into a metal conductor. The metal can be added to the grooves by one or more electroplating techniques known to those of skill in the art such as, for example, electrolytic or electroless plating. In one preferred process of this invention for filling the grooves with a conducting metal, the grooved wafers are first immersed in a solution of hydrofluoric acid and rinsed in de-ionized water. The wafers are then immersed in commercially available electroless nickel plating solution to deposit a layer of nickel such as, for example, a layer about 0.05 to about 0.2 micrometers, followed by a rinse in de-ionized water and drying. The wafers are then heated to a temperature of about 350° C. to about 450° C. for about 5 to about 20 minutes to sinter the nickel. The wafers are then treated to apply a layer of copper to the nickel. The layer of copper can be about 2 to about 10 micrometers in thickness. In such a treatment the wafer is immersed in nitric acid and then rinsed with water, then immersed in hydrofluoric acid, and then rinsed in water, then immersed in commercially available electroless nickel solution, then rinsed in water, then immersed in commercially available electroless copper solution, then rinsed in water, then immersed in a silver potassium cyanide solution and then rinsed in water and dried. Such procedure applies a conductive copper layer to the grooves and to the back surface at the same time thereby completing the back and front contact. It is not, however, necessary to apply the conductive metal to the grooves on the front surface of the wafer and to the back surface of the wafer at the same time. It is convenient to use the above-described electroless method for applying the conductive metals to apply both the front and back electrical contacts at the same time using the same process steps and chemical solutions. The back electrical contact can be applied separately by, for example, deposition of a layer comprising one or more conductive metals such as silver, aluminum, copper, tin, gold, platinum, cobalt and the like, to the back surface by one or more methods known in the art such as by sputtering or vaporization. Methods for filling the grooves with a conductive metal are also disclosed in European Patent Application Publication Number 1182709, Jensen et al., published on Feb. 27, 2002, which is incorporated herein by reference.

If desired, photovoltaic cells made by the process just described can be edge isolated by, for example, laser scribing around the front or rear surface at or very near the edge of the cell and then, preferably, physically breaking off the edge of the cell to electrically separate the front and back sides of the cell from each other. Other methods for edge isolation can also be used such as mechanically grinding or cutting off the edge of the cell.

The photovoltaic cells of this invention have high efficiency in converting light energy into electrical energy. Photovoltaic cells of this invention made using a silicon wafer have an efficiency of at least about 18 percent, more preferably at least about 18.3 percent, and still more preferable an efficiency of at least about 19 percent or at least about 19.2 percent. Photovoltaic cells of this invention made using a silicon wafer, for example, a monocrystalline silicon wafer, can have an efficiency of at least about 19.5 percent, and can have efficiency of up to or at least about 20 percent. The photovoltaic cells of this invention can be made having an efficiency of at least about 18 percent or at least about 18.3 percent using silicon wafers, such as Cz wafers, where the wafers have high levels of oxygen atoms and high levels of carbon atoms. Thus, the photovoltaic cells of this invention can be made having an efficiency of at least about 18 percent, or at least about 18.3 percent, using silicon wafers having greater than about 1×10¹⁷, or at least about 2×10¹⁷ (for example, about 5×10¹⁷ ) oxygen atoms per cubic centimeter of the silicon wafer, and greater than about 5×10¹⁵, or at least about 6×10¹⁵ (for example, about 1×10¹⁶) carbon atoms per cubic centimeter of the silicon wafer. The preferred wafer used for the photovoltaic cells of this invention is a monocrystalline Cz silicon wafer. As used herein, the efficiency of the solar cells made by the process of this invention is measured using the standard test conditions of AM1.5G at 25° C. using 1000 W/m² (1000 watts per square meter) illumination where the efficiency is the electrical energy output of the cell over the light energy input, expressed as a percent.

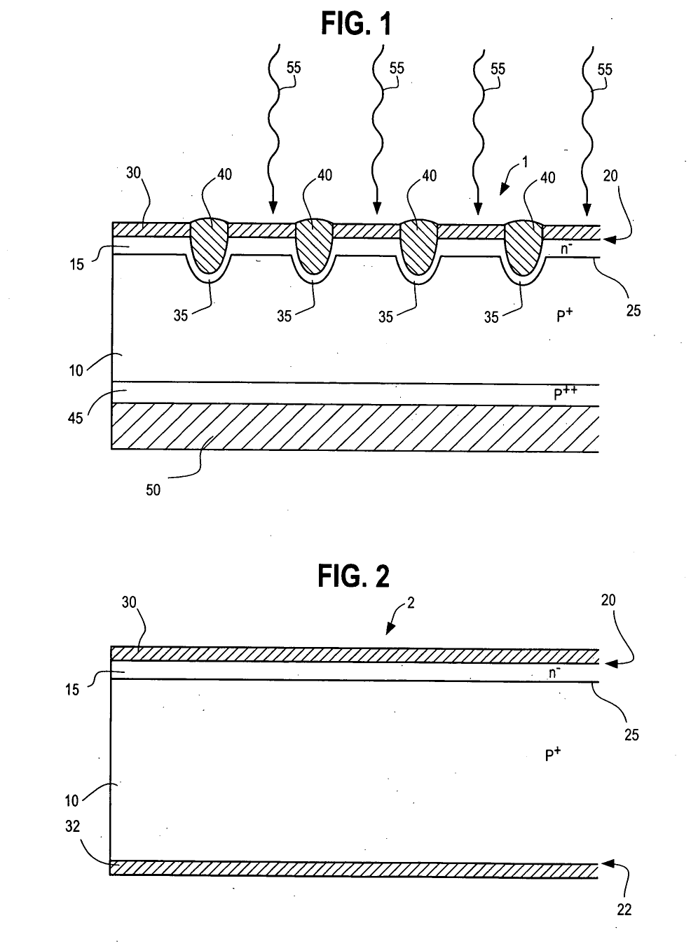

FIG. 1 shows a cross-section of a part of photovoltaic cell 1 made in accordance with an embodiment of the process of this invention. The photovoltaic cell 1 of FIG. 1 has a boron, p-doped, single crystalline silicon (Cz type) wafer 10. An n-doped layer 15, formed by phosphorus diffusion, is present next to the front surface 20 of silicon wafer 10. A p-n junction 25 is present where the boron doped substrate 10 meets the n-doped layer 15. Silicon nitride coating 30 has been applied over the n-doped layer 15. Heavily doped n-layer 35 is under each buried contact 40. The back surface field layer 45 is within the silicon substrate 10 and adjacent to back metal contact 50. Cell segment 1 is shown receiving incident solar radiation 55 on light receiving, front face 20.

FIG. 2 shows a cross-section of a part of coated semiconductor substrate 2 in accordance with an embodiment of this invention. FIG. 2 shows boron, p-doped, single crystal silicon substrate in form of a wafer 10. An n-doped layer 15, formed by, for example, phosphorus diffusion, is present next to the front face 20 of silicon wafer 10. A p-n junction 25 is present where the boron doped substrate 10 meets the n-doped layer 15. Silicon nitride surface coating 30 has been applied over the n-doped layer 15. Silicon nitride protective coating 32 has also been applied over the back face 22 of silicon substrate 10.

U.S. Provisional Patent Application No. 60/532,268 filed on Dec. 23, 2003, is hereby incorporated by reference in its entirety.

The advantageous efficiency of the photovoltaic cells of this invention is demonstrated by the following examples. These examples are being provided to illustrate certain embodiments of the invention and are not intended to limit in any way the scope thereof.

### EXAMPLES 1 AND 2 OF THE INVENTION

Examples 1 and 2 are examples of solar cells having an area of 147 cm² that were prepared using the general process and in the order of process steps in accordance with this invention as follows:

1. Starting Material

The silicon wafers used were conventional Cz silicon wafers doped p-type with boron to a resistivity of 1.2 ohm.cm and grown with [100] crystal planes parallel to the wafer surface. The wafer dimensions were 127 millimeters square with rounded corners of a diameter 150 millimeters. The wafer thickness was 300 micrometers. Such wafers are commercially available, for example, from Bayer Solar GmbH, PV Silicon GmbH or Pillar.

2. Wafer Surface Preparation

The wafers were anisotropically “texture” etched in a solution of sodium hydroxide and propanol at a temperature of 90° C. and cleaned by subsequent immersions in hydrofluoric acid and hydrochloric acid with intermediate and final rinsing in de-ionized water followed by drying.

3. Phosphorus Doping

Wafers were placed in pairs (touching) in the slots in a quartz wafer carrier and treated in an atmosphere of POCl₃ vapor and oxygen at a temperature of 780° C. to deposit a 10 nanometer thick film of phosphorus glass on the exterior surfaces.

4. Silicon Nitride Deposition

The wafers were treated in an atmosphere of silicon nitride and ammonia gases at a pressure of 33 Pa and a temperature between 780° C. and 860° C. to deposit a 130 nanometers thick film of silicon nitride on both the front and back surfaces of the silicon wafer.

5. Laser Grooving

A number of grooves were cut into the front surface (the surface with the silicon nitride film) that would subsequently form the conductive grid by which the electrical current is carried. Each groove had dimensions of typically 20 micrometers in width and 40 micrometers in depth and was formed by laser ablation of the surface material using a Nd:YAG laser Q-switched at a frequency of 50 kHz and traversing the wafer surface with a velocity of 500 millimeters/second. The groove pattern comprised a first group of parallel lines 1.5 millimeters apart distributed over the entire wafer surface, and a second group of grooves perpendicular to the first group and joined in two bundles with a distance of about 6 centimeters between each bundle. Each bundle comprised parallel grooves within a bundle width of 1.5 millimeters.

6. Groove Cleaning

The action of laser grooving generally results in silicon debris on the wafer surface and groove sidewalls that contain undesirable crystal imperfections. Accordingly the wafers were etched in a solution of sodium hydroxide at 64° C. to dissolve the silicon debris and etch the groove walls to a depth of a few microns. The wafers were then cleaned by subsequent immersions in hydrofluoric acid and hydrochloric acid with intermediate and final rinsing in de-ionized water followed by drying.

7. Groove Doping

The silicon wafers were placed in a quartz wafer carrier, inserted into a quartz tube and treated in an atmosphere of POCl₃ vapor and molecular oxygen at a temperature of 950° C.-1000° C. for 5 to 10 minutes with a subsequent drive-in step for 10-20 minutes to dope phosphorus into the exposed silicon surface to a sheet resistivity of about 8 ohm/square.

8. Plasma Etch

The silicon nitride layer on the back surface of the wafer was removed by etching in a gas plasma formed with Freon and oxygen. This was achieved by placing the wafers with their front surfaces touching each other and exposing the rear surfaces to the gas plasma or by placing the wafers with the front side facing down on a glass plate.

9. Aluminum Deposition

A 1-2 micrometer thick film of aluminum was deposited on the rear wafer surface by sputtering.

10. Aluminum Sintering

The silicon wafers were placed in a quartz wafer carrier that was inserted into a quartz tube in a mixture of molecular oxygen and nitrogen and heated for about 30 minutes at 900° C.- 1000° C.

11. Nickel Plating

The wafers were immersed in a solution of 4% hydrofluoric acid for 90 seconds and rinsed in de-ionized water. The wafers were then immersed in an alkaline electroless nickel plating solution (Enplate Al-100) for 100 s to deposit 0.1 micrometer nickel film followed by a rinse in de-ionized water before drying.

12. Nickel Sintering

The nickel-plated wafers were heated to a temperature of 400° C. for 6 minutes in a nitrogen atmosphere to sinter the nickel into the silicon surface.

13. Copper Plating

Wafers were treated using the following procedure to apply a 5 micron thick film of copper in the grooves and on to the rear surface of the wafer. A 2 minute immersion in 30% nitric acid was followed by a 10 minute rinse in water, a 30 second immersion in 1% hydrofluoric acid, a 10 minute rinse in water, a 60 second immersion in an acid electroless nickel solution (Enplate Ni-416) at a temperature of 90° C., a 30 second rinse in water, a 120 minute immersion in electroless copper solution (Enplate Cu-703) at a temperature of 50° C., a 10 minute rinse in water, a 6 minute immersion in a solution of silver potassium cyanide at room temperature, and a 10 minute rinse in water followed by drying.

14. Edge Isolation

The undesired electrically conductive deposits of nickel and copper on the edges were removed by cutting a groove to a depth of 100-150 micrometers into the silicon surface on the rear of the wafer and around the perimeter at a distance of 1 millimeter from the wafer edge. Cleaving and discarding the 1 millimeter silicon at the edge then removed the edge material.

Table 1 below shows the results of the testing of photovoltaic cells made by the process of this invention.

### COMPARATIVE EXAMPLE 3

Example 3, the comparative example, was carried out according to the prior art process, in that the “Groove Doping” step above was carried out before the “Aluminum Deposition” and “Aluminum Sintering” steps and the back surface of the wafer was not protected by a coating of silicon nitride or other protective coating in accordance with the process of this invention. Table 3 also shows the results for Comparative Example 3.

TABLE 1

| | | Area | Jsc | Voc | FF | Efficiency |
|---|---|---|---|---|---|---|
| | Material | [cm²] | [mA/cm²] | [mV] | [%] | [%] |
| Example 1 | Cz wafer | 147.3 | 36.28 | 625.1 | 80.6 | 18.3 |
| Example 2 | FZ wafer | 138.1 | 38.22 | 625.4 | 80.2 | 19.2 |
| Example 3 | Cz wafer | 147.3 | 36.4 | 619.0 | 79.1 | 17.8 |
| comparison | | | | | | |

Jsc = short circuit current of cell per square centimeter under 1000 W/m² illumination with AM1.5G spectrum
Voc = open circuit voltage of cell under 1000 W/m² illumination with AM1.5G spectrum
Efficiency = electrical energy output over light energy input measured under 1000 W/m² illumination using AM1.5G at 25° C.
FF = Fill Factor, a measure of power out/(Isc * Voc)
FZ means “float zone”
The results of example 1 and 2 were independently confirmed by CalLab of Fraunhofer Institute for Solar Energy Systems, Freiburg, Germany.

The process disclosed herein is useful for manufacturing highly efficient solar cells. The semiconductor wafer disclosed herein is useful for making solar cells.

Only certain embodiments of the invention have been set forth and alternative embodiments and various modifications will be apparent from the above description to those of skill in the art. Those and other alternatives are considered equivalents and are within the spirit and scope of the invention.

1. A process for making a photovoltaic cell using a semiconductor wafer doped with a first dopant and having a front surface and a back surface, the process comprising the steps of:
(a) forming a first layer on the front surface of the wafer, the first layer comprising a second dopant of a conductivity type opposite the first dopant;
(b) depositing a surface coating on the back surface;
(c) forming grooves in the front surface;
(d) adding dopant to the grooves of a conductivity type opposite the first dopant subsequent to depositing the surface coating on the back surface;
(e) removing the surface coating from the back surface after adding dopant to the grooves;
(f) forming a back contact over the back surface after removal of the surface coating; and
(g) adding conductive material to the grooves.

2. The process of claim 1 further comprising depositing a surface coating on the front surface over the first layer and forming the grooves in the front surface after depositing the surface coating thereon.

3. The process of claim 2 wherein the surface coating on the front surface and on the back surface comprise the same coating material.

4. The process of claim 2 wherein the surface coating on the front surface and on the back surface are applied at the same time.

5. The process of claim 4 wherein the surface coating comprises a dielectric.

6. The process of claim 5 wherein the surface coating comprises silicon nitride.

7. The process of claim 2 wherein the surface coating on the back surface is removed by plasma etching.

8. The process of claim 2 wherein the semiconductor wafer comprises silicon and is p-doped and the dopant added to the grooves is an n-dopant.

9. The process of claim 1 further comprising forming a back surface field.

10. A photovoltaic cell comprising:
(a) a semiconductor wafer comprising silicon doped with a first dopant, the wafer having a front surface and a back surface;
(b) a first layer comprising a second dopant of a conductivity type opposite to the first dopant positioned over the front surface;
(c) an antireflective coating positioned over the front surface;
(d) a front contact buried in the front surface;
(e) a back contact over the back surface; and
(f) a back surface field
wherein the wafer used to make the photovoltaic cell contains greater than about 1×10¹⁷ atoms of oxygen per cubic centimeter of wafer and the efficiency of the cell is at least about 18 percent measured using AM 1.5G at 25° C. under 1000 W/m² illumination.

11. The photovoltaic cell of claim 10 wherein the wafer used to make the photovoltaic cell has greater than 5×10¹⁵ atoms of carbon per cubic centimeter of wafer.

12. The photovoltaic cell of claim 10 wherein the wafer used to make the photovoltaic cell has greater than or equal to about 2×10¹⁷ atoms of oxygen per cubic centimeter of wafer.

13. The photovoltaic cell of claim 10 wherein the wafer used to make the photovoltaic cell has greater than or equal to about 6×10¹⁵ atoms of carbon per cubic centimeter of wafer.

14. The photovoltaic cell of claim 10 wherein the wafer used to make the photovoltaic cell has greater than or equal to about 2×10¹⁷ atoms of oxygen per cubic centimeter of wafer and greater than or equal to about 6×10¹⁵ atoms of carbon per cubic centimeter of wafer.

15. The photovoltaic cell of claim 10 wherein the wafer used to make the photovoltaic cell is a Cz wafer.

16. The photovoltaic cell of claim 10 wherein the efficiency of the cell is at least about 18.3 percent.

17. A semiconductor wafer useful for manufacturing photovoltaic cells comprising:
(a) a semiconductor wafer doped with a first dopant, the wafer having a front surface and a back surface;
(b) a first layer comprising a second dopant of a conductivity opposite the first dopant positioned over the front surface;
(c) an antireflective coating positioned over the front surface; and
(d) a surface coating positioned over the back surface.

18. The semiconductor wafer of claim 17 wherein the antireflective coating positioned over the front surface and the surface coating positioned over the back surface comprise silicon nitride.

19. A process for making a photovoltaic cell using a wafer comprising silicon and doped with a first dopant and having a front surface and a back surface, the process comprising the steps of:
(a) forming a first layer on the front surface of the wafer, the first layer comprising a second dopant of a conductivity type opposite the first dopant;
(b) depositing a surface coating on the back surface and on the front surface at the same time;
(c) forming grooves in the front surface after depositing the surface coating thereon;
(d) adding dopant to the grooves of a conductivity type opposite the first dopant to the grooves subsequent to depositing the surface coating on the back surface;
(e) removing the surface coating from the back surface after adding dopant to the grooves;
(f) forming a back contact over the back surface after removal of the surface coating; and
(e) adding a conductive material to the grooves.

19. The process of claim 18 wherein the surface coating applied to the front surface and the back surface is silicon nitride.

20. The process of claim 18 wherein the process steps are conducted in the order (a), (b), (c), (d), (e), (f), (g).

21. The process of claim 1 wherein the process steps (a), (b), (c), (d), (e) are conducted in that order.
